(19) United States
(12) Patent Application Publication
(10) Pub. No.: US 2011/0012627 A1
(43) Pub. Date: Jan. 20, 2011

(54) Method for determining porosity with high frequency conductivity measurement

(75) Inventors: Andrei Dukhin, Goldens Bridge, NY (US); Philip J. Goetz, Essex, NY (US)

Correspondence Address: Andrei Dukhin, 364 Adams Street, Bedford Hills, NY, 10507, US

(73) Assignee: Dispersion Technology Inc, Bedford Hills, NY (US)

(21) Appl. No.: 12/806,825

(22) Filed: Aug. 23, 2010

(51) Int. Cl. G01R 27/08

(52) U.S. Cl. 324/699

(57) ABSTRACT

Propagation of ultrasound through a porous body saturated with liquid generates electric response.

### FIELD OF THE INVENTION

Characterization of porosity.

### BACKGROUND OF THE INVENTION

This invention deals with a particular kind of heterogeneous system, which can be described as a porous body consisting of a continuous solid matrix with embedded pores that can be filled with either gas or liquid. According to S. Lowell et al, the spatial distribution between the solid matrix and pores can be characterized in terms of a “porosity”. Although methods exist for characterizing this parameter, they all have limitations and call out for improvement.

According to IUPAC, pores are classified into three classes: micropores (pore size<2 nm); mesopores (pore size between 2 and 50 nm); and macropores (pore size>50 nm). S. Lowell et al describe in detail several methods for characterizing porosity for all these pores. Gas adsorption techniques are typically used for analysis of micropores and mesopores, whereas mercury porosimetry has been the standard technique for macropore analysis. Environmental concerns justify a search for alternative to methods for macropore analysis that might eliminate, or at least minimize, the use of this dangerous mercury material.

There have been various attempts to design porosity meters by applying either mechanical (ultrasound), electrical, or magnetic fields to a particular porous body.

Ultrasound methods for characterizing porous bodies rely on changes in the sound wave as it propagates though a saturated porous body and, in the process, generates a host of secondary effects that can then be used for characterizing the properties of these bodies. To date, most attempts are associated with the measurement of sound speed and attenuation, the two main characteristics of ultrasound waves propagating through a visco-elastic media. These two parameters are easily measurable and, in principle, can serve as a source of information for calculating porosity and pore size. U.S. Pat. No. 6,684,701 issued Feb. 3, 2004, to Dubois et al describes a method for extracting porosity by comparing the measured attenuation spectra with that of predetermined standards. U.S. Pat. No. 6,745,628, issued Jun. 8, 2004, to Wunderer claims to measure porosity based on transmission measurements of ultrasonic waves in air, which might be possible only for very large pores comparable to the sound wavelength, which for the proposed low frequency is perhaps several millimeters. Yet another U.S. Pat. No. 7,353,709, issued Apr. 8, 2008, to Kruger et al., suggests some improvements in this method, but still relies on comparison with attenuation standards to extract the porosity information from the raw data. There are also several patents describing the use of ultrasound for characterizing the porous structure of bone. One example is U.S. Pat. No. 6,899,680, issued May 31, 2005, to Hoff et al. for estimating ? the shear wave velocity, but not attenuation. There are also two patents that utilize differences in sound speed between different propagation modes. The first is U.S. Pat. No. 5,804,727, issued Sep. 8, 1998, to Lu et al., that simply states that a person skilled in the art would recognize that velocities of different modes could be used for determining the physical properties of materials. The second, U.S. Pat. No. 6,959,602, issued Nov. 1, 2005, to Peterson et al., suggests that, based on a prediction by Biot, one might use the velocity of fast compression waves for calculating porosity and slow compression waves for detecting body defects.

However, analysis of the Biot theory raises many concerns about the efficacy of using ultrasound attenuation and sound speed for characterizing porous bodies. M. A. Biot in 1956, crediting the earlier work by J. Frenkel, developed a well-known general theory of sound propagation through wet porous bodies by including the following set of eleven physical properties to describe the solid matrix and liquid:
1. density of sediment grains
2. bulk modulus of grains
3. density of pore fluid
4. bulk modulus of pore fluid
5. viscosity of pore fluid
6. porosity
7. pore size parameter
8. dynamic permeability
9. structure factor
10. complex shear modulus of frame
11. complex bulk modulus of frame

Ogushwitz recognized that the last four of these properties present a big problem in applying Biot's theory and proposed several empirical and semi-empirical methods for estimating their value, but none of his suggestions are sufficiently general, and in some cases simply amount to a substitution of one property with another unknown constant. Barret-Gultepe et al also discuss this problem in their study of the compressibility of colloids, in which they speak of the importance of a “skeleton effect” and the difficulty of measuring the required input parameters independently.

This problem of unknown input parameters makes us skeptical of determining porosity and pore sizes from attenuation and sound speed.

There is one U.S. Pat. No. 7,500,539, issued Mar. 10, 2009, to Dorovsky et al., suggesting the application of crossed magnetic fields for measuring porosity. These fields would generate deformation at interfaces with the rate depending on the amplitude of the field. Calculation of porosity would require information on electric conductivity and permeability of the porous body, which are unknown within this method and would require additional independent measurement.

Another group of new methods suggests using an electric field for sensing the properties of porous bodies including porosity. The porous body is usually assumed as being saturated with a conducting aqueous solution. The motion of ions under the influence of the applied electric field generates an electric current, which in turn depends on value of the electric conductivity. Measurement of this current for known applied electric field yields information on electric conductivity. A higher conductivity indicates more ions present in the pores of the porous body. This can be used for monitoring the amount of space that is available for the water carrying these ions. The ratio of this space to the total volume of the porous body corresponds to the desired porosity value.

The applied electric field might be constant in time (DC mode) or oscillating in time (AC mode) with certain frequency ω. Both modes for applying the electric field have been suggested for characterizing porosity.

Lyklema and Minor used DC electric field for calculating the porosity of the plugs formed by sedimenting particles. They measured the conductivity of the plug and the conductivity of the equilibrium supernate, and then applied appropriate theory for calculating the plug porosity. They intentionally conducted this experiment under conditions of substantial surface conductivity. This factor can be eliminated by using an aqueous solution having a high ionic strength, as suggested by Milsch et al. This last group also used the ratio of porous body conductivity and equilibrium supernate conductivity for studying the structure of the body and refers to this ratio as a “formation factor”.

However, there are several problems in using a DC field for characterizing porosity, some of which are mentioned by Milsch et al. First, conductivity measurement in a DC field is complicated by possible electrode polarization and electrochemical reactions. Secondly, only pores that percolate from one electrode to another would contribute to the conductivity of the porous body. This method is not applicable at all to the porous bodies with intricate pore structure including closed pores.

The application of high frequency electric fields allows easy resolution of both of these problems. Electrode polarization becomes negligible for MHz frequencies. This allows construction of the probe with very simple flat geometry, as described below. Additionally, due to capacitive coupling high frequency electric fields penetrates all pores, even closed pores. This means that conductivity measured at high frequency would reflect the motion of ions in all pores of the porous body where saturating liquid could penetrate.

There are three U.S. patents suggesting the use of high frequency conductivity measurements for characterizing porosity: U.S. Pat. No. 5,349,528, issued Sep. 20, 1994, to Ruhovets, U.S. Pat. No. 5,457,628, issued on Oct. 10, 1995 to Theyanayagam, U.S. Pat. No. 4,654,598, issued Mar. 31, 1987 to Arulanandan et al. Instead of measuring a “formation factor” at high frequency, they suggest measuring the frequency dependence of the electrical conductivity. These three patents all target remote characterization of soils, which makes it impossible determination the conductivity of an equilibrium supernate that would be required for calculating “formation factor”.

In contrast, our target in this patent is the characterization of porous bodies such as geological cores, or chromatographic materials that are available in a laboratory environment and hence an equilibrium supernate can be readily prepared.

The novel idea of this patent is the measurement of the “formation factor” of the porous body saturated with high conducting water electrolyte at high frequency, typically several MHz. This experimental raw data is sufficient for application of the well-known Maxwell-Wagner theoretical model, which can yield the value for the porosity.

We present here one possible embodiment of this idea and a verification of the suggested method for number of real porous bodies with widely variable porosity.

### BRIEF SUMMARY OF INVENTION

The applicant describes a new method of determining porosity by measuring the high frequency electrical conductivity of a porous body saturated with highly conducting water electrolyte and conductivity of the equilibrium supernate, the ratio of which is a “formation factor”. The porosity is calculated from this formation factor using well-known theory. The applicant also presents a particular design of the conductivity probe suitable for measuring the conductivity of the porous body and verification of its function for variety of porous bodies with having a wide range of porosity.

### BRIEF DESCRIPTION OF THE DRAWINGS

FIG. 1 illustrates design of the overall porosity meter, including the electronics and the probe.

FIG. 2 illustrates the relationship between the porosity measured using this invention and independently known values for variety of porous bodies.

### DETAILED DESCRIPTION OF INVENTION

The following detailed description of the invention includes: a description of the conductivity electronics and probe hardware required to practice the invention by measuring the conductivity of both the porous body and an equilibrium supernate; a theoretical treatment based on a Maxwell-Wagner model that discusses the calculation of porosity from these two measured conductivities, and verification tests using several porous bodies having known independently measured porosity.

Hardware Description

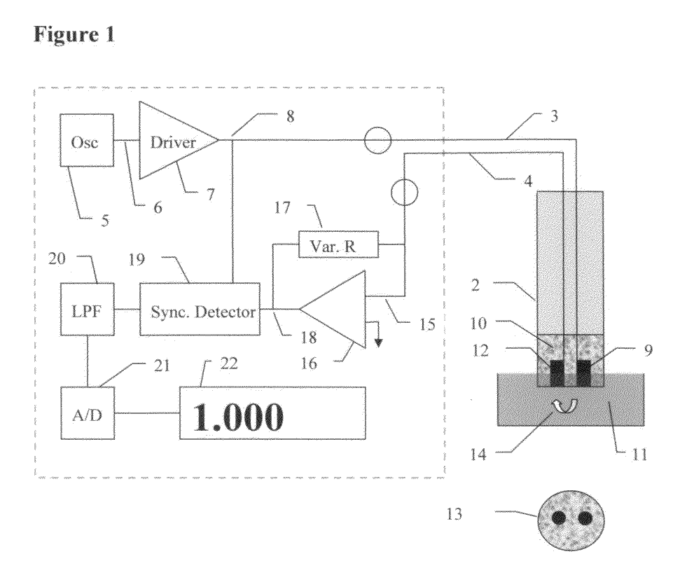

As shown in FIG. 1, the porosity meter consists of two parts: the porosity electronics shown inside the dotted border 1 and the porosity probe 2 connected to the electronics by drive coax cable 3 and sensing coax cable 4.

Said electronics contains an RF oscillator 5 that provides a sine wave output 6 at a frequency of typically 3 MHz. Said sine wave output is amplified to a level of typically 1 V rms by a Driver amplifier 7, which provides a low output impedance drive signal 8, the level of which is independent of any load impedance. Said drive signal is connected via said drive coax cable 3 to a drive electrode 9, which is imbedded in a flexible rubber-like compound 10 at the tip of said porosity probe.

Said porosity probe also contains a sensing electrode 12, adjacent to but not touching the drive electrode, as illustrated in end view 13 of said porosity probe. Said sensing electrode is maintained at zero voltage, and consequently a current 14 will flow from said drive electrode to said sensing electrode, said current being proportional to the conductivity of said reference fluid.

Said sensing electrode is connected to the summing point 15 of operational amplifier 16 via said coax cable 4. Said operational amplifier is used as a current amplifier, which maintains the input voltage as a virtual ground, as is well known to one skilled in the art. The current gain of said current amplifier is determined by the resistance value of potentiometer 17.

The current signal output 18 of said current amplifier is connected to a synchronous detector 19 that is keyed by said drive signal 8. The direct current (dc) component of the output of said synchronous detector output is proportional to the real part of the complex conductivity of the reference fluid. Said synchronous detector output is connected to a low pass filter 20 to remove the alternating current (ac) component of the signal. The output of said low pass filter is connected to the input of an analog to digital converter (A/D) 21. The output of said A/D provides suitable reading on a 4 digit digital display 22.

Measurement of the porosity of a body is a two-step process. In the first step the probe is immersed in the reference fluid, which is supernate in equilibrium with the liquid that saturates porous body. Said potentiometer is adjusted such that said digital display reads full scale, typically scaled such that the display reads a value of 1.000.

In the second step, the probe is put in contact with the porous body. The flexible tip at the end of the probe insures that not only do the two electrodes make intimate contact with the porous body, but additionally that said flexible tip excludes any reference fluid from the space between the electrodes. Importantly, all current that passes between the electrodes must pass through the porous body.

Theoretical Treatment

There is well-known and well-verified theory that predicts the difference between the conductivity of a heterogeneous system Kₛ and that of an equilibrium supernate Kₘ. This theory was developed more than a hundred years ago by Maxwell and Wagner, and yields the surprisingly simple expression for the formation factor:

$$\frac{{K}_{s}}{{K}_{m}} = \frac{2 P}{3 - P} \qquad ( 1 )$$

where P is the porosity, which can also be expressed as (1−φ), where φ is the volume fraction of solids.

This theory can be applied to liquid dispersions, as well as to the porous bodies. In the case of dispersions volume fraction of solids φ is used instead of porosity. These two parameters are linked with a simple conservation law:

P=1−φ (2)

This simple expression of Maxwell-Wagner theory is based on several assumptions:
1. the dispersed phase is non-conducting
2. the dispersion medium is conducting
3. the surface conductivity is negligible
4. the frequency of the electric field oscillation ω is much less than so-called Maxwell-Wagner frequency ω_{MW}, which depends on conductivity:

$$ω << {ω}_{MW} = \frac{{K}_{m}}{{ɛ}_{0} {ɛ}_{m}}$$

where ε₀ and εₘ are permittivity of the vacuum and medium.

Conditions 1 and 2 are valid for practically all porous bodies.

Condition 3 can be met by using a highly conducting aqueous electrolyte solution for saturating the porous body, such as 0.1 M KCl.

Condition 4 can be met if the frequency lies in the range from 1 to 10 MHz, keeping in mind that Maxwell-Wagner frequency of 0.1 M KCl solution is about 200 MHz.

It is not desirable to reduce frequency below 1 MHz due to potential effect of electrodes polarization, which is completely suppressed at MHz range frequencies. Elimination of the electrode polarization allows tremendous simplification of the conductivity probe design.

Verification Test

We used four different systems for verification of the Maxwell-Wagner theory validity, one dispersion and three porous bodies.

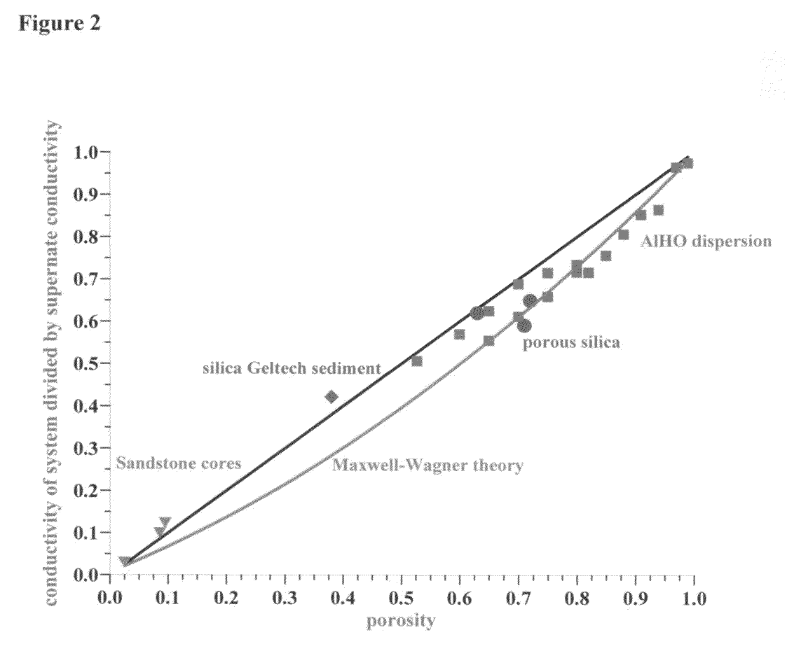

The first system represented liquid dispersion of AlHO in water. It allowed us test Maxwell-Wagner theory at the range of low and intermediate volume fractions (high porosity). We had this originally concentrated dispersion with the volume fraction at about 50% vl. It was centrifuged for extracting equilibrium supernate. We measured conductivity of this supernate for further calculation of the “formation factor” for a set of diluted dispersions. We performed this equilibrium dilution of the original concentrated dispersion with the supernate from 50% vl down to 1% vl in steps. We measured conductivity of the each dispersions created by this dilution procedure. Ratio of these conductivities to the conductivity of the supernate yielded “formation factor” for the each dispersion. These numbers were plotted on FIG. 2 versus known volume fraction (porosity) for each dispersion.

In order to test validity of the method and Maxwell-Wagner theory at the range of low porosity (high volume fraction of solids) we used three porous systems:

1) a series of sediments formed by large porous silica particles;

2) a sediment formed by 1.5 micron solid silica particles, and

3) a series of three solid sandstone cores of known porosity.

The sediments of porous particles were formed with four different porous chromatographic silica CPG powders provided by Quantachrome Corporation, each having the same porosity but a different pore size. The sediments were built directly on the surface of the conductivity probe. There were two contributions to the total measured porosity: the void space between large 100 micron porous particles and the interior porosity within the particles. The interior porosity of these samples was measured using mercury intrusion and extrusion experiments. The experiments were performed over a wide range for pressures starting in vacuum and continuing up to 60000 psi (1 psi=6.895×10⁻³ MPA) using a Quantachrome Poremaster 60 instrument. These pore size and porosity values are shown in Table 1.

TABLE 1
Porosity and pore size for five different CPG samples.

| | | | | | |
|---|---|---|---|---|---|
| Pore size [nm] | 12 | 40.6 | 63.7 | 92.4 | 136 |
| Porosity, % | 51.3 | 70.2 | 72.2 | 63.5 | 70.9 |

We measured formation factors for all four sediments and plotted them on FIG. 2 as the function of the known porosity presented in Table 1.

Next porous body was a sediment of solid 1.5 micron silica Geltech particles. Again, the particles were deposited directly on the surface of the conductivity probe. We estimated the porosity of this deposit from the time of its formation as described ion the paper by Dukhin, Goetz, and Thommes. Measured formation factor of this deposit is shown on FIG. 2 as a function of the estimated porosity.

The last model system were three solid geological sandstone cores from the different mines. They are marked according to the place of origin as: Ohio, Berea and Orchard. These cores are examples of a truly porous body as compared to the sediment plugs considered in the above three examples. The cores were saturated with 0.1 M KCl solution. The cores were placed on their sides in order to expose both circular faces of these cylindrical plugs to the solution and to allow simultaneous equilibration. Porosity of these cores were measured using a Quantachrome Poremaster 60 instrument. It is shown in Table 2.

TABLE 2
Porosity and pore size for three different sandstone cores.

| | Ohio | Berea | Orchard |
|---|---|---|---|
| Pore size [micron] | 0.6 | 12.8 | 0.34 |
| Porosity, % | 0.086 | 0.095 | 0.025 |

Measured formation factors for all sandstone cores are shown on FIG. 2 as functions of the independently known porosity.

There is also solid line on FIG. 2 that represents formation factor as function of porosity according to the Maxwell-Wagner, theoretical equation 1. It is seen that there is very good agreement between experiment and theory. This is experimental confirmation of the suggested porosity measurement method.

U.S. PATENT DOCUMENTS

| | | | |
|---|---|---|---|
| 4,654,598 | March 1987 | Arulanandan | 324/354 |
| 5,349,528 | September 1994 | Ruhovers | 702/7 |
| 5,457,628 | October 1995 | Theyanayagam | 702/8 |
| 5,804,727 | September 1998 | Lu Wei-yang et all | 73/597 |
| 6,684,701 | July 2004 | Dubois et al. | 73/579 |
| 6,745,628 | June 2004 | Wunderer | 73/579 |
| 6,899,680 | May 2005 | Hoff et al. | 600/449 |
| 6,959,602 | November 2005 | Peterson et al. | 73/602 |
| 7,353,709 | April 2008 | Kruger et al. | 73/599 |
| 7,500,539 | March 2009 | Dorovsky | 181/102 |

### OTHER PUBLICATIONS

1. Lowell, S., Shields, J. E., Thomas, M. A. and Thommes, M. “Characterization of porous solids and powders: surface area, pore size and density”, Kluwer Academic Publishers, The Netherlands, 2004.
2. Biot, M. A. “Theory of propagation of elastic waves in a fluid-saturated porous solid. 1. Low frequency range. J. Acoustic Society of America, vol. 28, 2, pp. 168-178[1956]
3. Biot, M. A. “Theory of propagation of elastic waves in a fluid-saturated porous solid. 1. High frequency range. J. Acoustic Society of America, vol. 28, 2, pp. 179-191[1956]
4. Frenkel J. “On the Theory of Seismic and Seismoelectric Phenomena in a Moist Soil”, J. of Physics, USSR, vol. 3, 5, pp. 230-241[1944], re-published J. Engineering Mechanics, [2005].
5. Ogushwitz, P. R. “Applicability of the Biot theory. 1. Low-porosity materials”, J. Acoustic Society of America, vol. 77, 2, pp. 429-440, 1984
6. Barrett-Gultepe, M. A., Gultepe, M. E. and Yeager, E. B. “Compressibility of colloids. 1. Compressibility studies of aqueous solutions of amphiphilic polymers and their adsorbed state on polystyrene latex dispersions by ultrasonic velocity measurements”, J. Phys. Chem., 87, 1039-1045, 1983.
7. Lyklema, J., “Fundamentals of Interface and Colloid Science”, vol. 1-3, Academic Press, London-NY, (1995-2000).
8. Lyklema, J. and Minor, M. “On surface conduction and its role in electrokinetics”, Colloids and Surfaces, A., 140, 33-41 (1998)
9. Milsch, H., Blocher, G., and Engelmann, S. “The relationship between hydraulic and electric transport properties in sandstones: An experimental evaluation of several scaling models”, Earth and Planetary Science Letters, 275, 355-363 (2008)
10. Gunnink, B. W., Enustun, B. V. and Demirel, T. “Determination of the pore structure of porous materials using electrical conductance”, Particulate Science and Technology, 6, 1, 105-117 (1988)
11. Maxwell, J. C. “Electricity and Magnetism”, Vol. 1, Clarendon Press, Oxford (1892)
12. Wagner, K. W., Arch. Elektrotech., 2, 371 (1914)
13. Dukhin, A. S., Goetz, P. J, and Thommes, M. “Seismoelectric effect: A non-isochoric streaming current. 1. Experiment”, J. Colloid and Interface Science, 345, p. 547-553 (2010)

We claim:

1. A method of determining porosity of porous material comprising the steps of:
saturating and equilibrating porous material with water based electrolyte solution having high ionic strength for eliminating surface conductivity contribution;
placing equilibrium supernate obtained after said porous material reached equilibrium in contact with a conductivity probe that conduct measurement at high frequency;
saving measured conductivity value;
placing conductivity probe in contact with said porous body and measuring its conductivity at the same frequency;
dividing measured conductivity by the saved conductivity of the supernate, this ratio is “formation factor”;
calculating porosity of the said porous body from the “formation factor” using appropriate theory.

2. A method of determining porosity of porous material as set forth in claim 1 where said electrolyte solution is has ionic strength 0.1 M/l;

3. A method of determining porosity of porous material as set forth in claim 1 where said frequency exceeds 100 KHz;

4. A method of determining porosity of porous material as set forth in claim 1 where said theory is Maxwell-Wagner theory;

5. An instrument suitable for measuring formation factor of porous material saturated with highly conducting reference liquid comprising of:
electronics block generating sine wave output at a high frequency specified in claim 3 and measuring flowing electric current;
conductivity probe with two electrodes that are imbedded in a flexible compound for matching unevenness of the porous body surface and force liquid out the gap between the probe and said porous body.
